(19) United States
(12) Patent Application Publication
(10) Pub. No.: US 2026/0157091 A1
(43) Pub. Date: Jun. 4, 2026

(54) DISPLAY PANEL AND DISPLAY DEVICE

(71) Applicants: Mianyang HKC Optoelectronics Technology Co., Ltd., Mianyang (CN); HKC Corporation Limited, Shenzhen (CN)

(72) Inventors: XIUFENG ZHOU, Mianyang (CN); Zhi Yang, Mianyang (CN); Yangling Tang, Mianyang (CN); Zhisheng Xie, Mianyang (CN); Qin Liang, Mianyang (CN); Haijiang Yuan, Mianyang (CN)

(21) Appl. No.: 19/385,152

(22) Filed: Nov. 11, 2025

(30) Foreign Application Priority Data
Nov. 29, 2024 (CN) 202411737148.3

(51) Int. Cl. H10K 59/80; H10K 59/122; H10K 102/00

(52) U.S. Cl. CPC H10K 59/879; H10K 59/122; H10K 59/873; H10K 2102/351

(57) ABSTRACT

A display panel and a display device are disclosed. The display panel includes a substrate, a pixel-defining layer, a light-emitting functional layer, a first micro-prism structure layer, a second micro-prism structure layer and an inorganic encapsulation layer; the pixel-defining layer is divided into a plurality of partitions, wherein interiors of the plurality of partitions are hollowed out internally to form a plurality of pixel regions; the inorganic encapsulation layer, the second micro-prism structure layer and the first micro-prism structure layer are sequentially stacked on the light-emitting functional layer; wherein both the first micro-prism structure layer and the second micro-prism structure layer are organic encapsulation structures, and a refractive index of the second micro-prism structure layer is greater than that of the first micro-prism structure layer.

### CROSS-REFERENCE TO RELATED APPLICATIONS

The present application claims the priority and benefit of Chinese patent application number 2024117371483, titled “DISPLAY PANEL AND DISPLAY DEVICE” and filed on Nov. 29, 2024 with China National Intellectual Property Administration, the entire contents of which are incorporated herein by reference.

### TECHNICAL FIELD

The present application relates to the technical field of display, and more particularly relates to a display panel and a display device.

### BACKGROUND

The description provided in this section is intended for the mere purpose of providing background information related to the present application but does not necessarily constitute prior art.

Organic Light-Emitting Diode (OLED) is an optoelectronic technology that utilizes organic semiconductor materials to achieve multicolor display through reversible color variation driven by electric current. OLED display panels have advantages including thinness and lightness, high luminance, active light-emission, low energy consumption, wide viewing angle, fast response, flexibility, and broad operating temperature range, and are therefore widely favored in the field of display panels. Currently, the conventional manufacturing method of OLED display panels is to define the material evaporation region through a Fine Metal Mask (FMM), and then complete the process through light-emitting manufacturing and Thin-Film Encapsulation (TFE) technology.

However, under a specific material system, the luminous efficiency of the light-emitting material is fixed, and the light-output amount at the front-view angle of the product basically tends to be stable. To increase light output, it is necessary to increase a drive current of the device to achieve an increase in light output at a front view and reach a display brightness required by a product. Nevertheless, such an approach may lead to an increase in overall power consumption of the product, which is not desired in product development. Therefore, before a new OLED material device system is developed, avoiding an increase in product power consumption while ensuring display brightness is a major competitive advantage of display products.

### SUMMARY

An objective of the present application is to provide a display panel and a display device, while guaranteeing display brightness, reducing product power consumption and improving market competitiveness.

The present application discloses a display panel, the display panel includes a substrate, a pixel-defining layer, a light-emitting functional layer, a first micro-prism structure layer, a second micro-prism structure layer and an inorganic encapsulation layer. The pixel-defining layer is disposed on the substrate, divided into a plurality of partitions, wherein interiors of the plurality of partitions are hollowed out internally to form a plurality of pixel regions. The light-emitting functional layer is disposed in the plurality of pixel regions. The first micro-prism structure layer is disposed on the light-emitting functional layer. The second micro-prism structure layer is disposed on the first micro-prism structure layer. The inorganic encapsulation layer is disposed on the second micro-prism structure layer. Both the first micro-prism structure layer and the second micro-prism structure layer are organic encapsulation structures, and a refractive index of the second micro-prism structure layer is greater than that of the first micro-prism structure layer.

The present application further discloses a display panel, the display panel includes a substrate, a pixel-defining layer, a light-emitting functional layer, a first micro-prism structure layer, a second micro-prism structure layer, an inorganic encapsulation layer and a plurality of condensing lenses. The pixel-defining layer is disposed on the substrate, divided into a plurality of partitions, wherein interiors of the plurality of partitions are hollowed out internally to form a plurality of pixel regions. The light-emitting functional layer is disposed in the plurality of pixel regions. The first micro-prism structure layer is disposed on the light-emitting functional layer. The second micro-prism structure layer is disposed on the first micro-prism structure layer, a thickness of the second micro-prism structure layer is less than that of the first micro-prism structure layer. The inorganic encapsulation layer is disposed on the second micro-prism structure layer. The plurality of condensing lenses are disposed on the plurality of partitions in one-to-one correspondence, the plurality of condensing lenses are located between the first micro-prism structure layer and the second micro-prism structure layer, and orthographic projections of the plurality of condensing lenses on the substrate cover orthographic projections of the plurality of partitions on the substrate. Both the first micro-prism structure layer and the second micro-prism structure layer are organic encapsulation structures, and the refractive index of the second micro-prism structure layer is greater than that of the first micro-prism structure layer.

The present application further discloses a display device, the display device includes a drive circuit and a display panel, the drive circuit drives the display panel. The display panel includes a substrate, a pixel-defining layer, a light-emitting functional layer, a first micro-prism structure layer, a second micro-prism structure layer and an inorganic encapsulation layer. The pixel-defining layer is disposed on the substrate, divided into a plurality of partitions, wherein interiors of the plurality of partitions are hollowed out internally to form a plurality of pixel regions. The light-emitting functional layer is disposed in the plurality of pixel regions. The first micro-prism structure layer is disposed on the light-emitting functional layer. The second micro-prism structure layer is disposed on the first micro-prism structure layer. The inorganic encapsulation layer is disposed on the second micro-prism structure layer. Both the first micro-prism structure layer and the second micro-prism structure layer are organic encapsulation structures, and a refractive index of the second micro-prism structure layer is greater than that of the first micro-prism structure layer.

The beneficial effects of embodiments of the present application are as follows: by adding the first micro-prism structure layer and the second micro-prism structure layer on the light-emitting functional layer, and with the refractive index of the second micro-prism structure layer being greater than that of the first micro-prism structure layer, the light emitted from the light-emitting functional layer converges towards the middle area of the display panel after passing through the first micro-prism structure layer and the second micro-prism structure layer, achieving the effect of increasing the front-side light-emitting brightness of the display panel. In this way, under the condition of guaranteeing the front-side light-emitting brightness of the display panel, it is possible to avoid increasing the light-emitting brightness of the light-emitting functional layer, so as to reduce the power consumption of the product, thereby improving the market competitiveness of the product. Moreover, the first micro-prism structure layer and the second micro-prism structure layer themselves are the encapsulation structures of the display panel, so the first micro-prism structure layer and the second micro-prism structure layer do not cause an increase in thickness of the display panel.

### BRIEF DESCRIPTION OF DRAWINGS

The accompanying drawings serve to provide a further understanding of the embodiments according to the present application, constitute part of the specification, are used to illustrate the embodiments according to the present application, and explain the principles of the present application in conjunction with the textual description. Apparently, the drawings in the following description are merely some embodiments of the present disclosure, and those having ordinary skill in the art may derive other drawings based on these drawings without exercising creative effort. In the drawings:

FIG. 1 is a schematic diagram of a display panel according to a first embodiment of the present application.

FIG. 2 is a schematic diagram of a display panel according to a second embodiment of the present application.

FIG. 3 is a schematic diagram of a display panel according to a third embodiment of the present application.

FIG. 4 is a schematic diagram of a display panel according to a fourth embodiment of the present application.

FIG. 5 is a schematic enlarged diagram of FIG. 4 at A.

FIG. 6 is a schematic diagram of a display device according to an embodiment of the present application.

### DETAILED DESCRIPTION OF EMBODIMENTS

It should be understood that the terms used herein, the specific structures and functional details disclosed therein are merely representative for describing some specific embodiments, but the present application may be implemented in many alternative forms and should not be construed as being limited to only the embodiments described herein.

Moreover, unless explicitly specified and defined otherwise, the terms “connected” and “linked” should be broadly understood. For example, such connections may be fixed connections, detachable connections, or integrally formed connections; mechanical connections or electrical connections; direct connections or indirect connections through an intermediary; or internal communication between two elements. A person skilled in the art may comprehend the specific meanings of the aforementioned terms in the present application based on practical circumstances.

The present application is described in detail below with reference to the accompanying drawings and some optional embodiments.

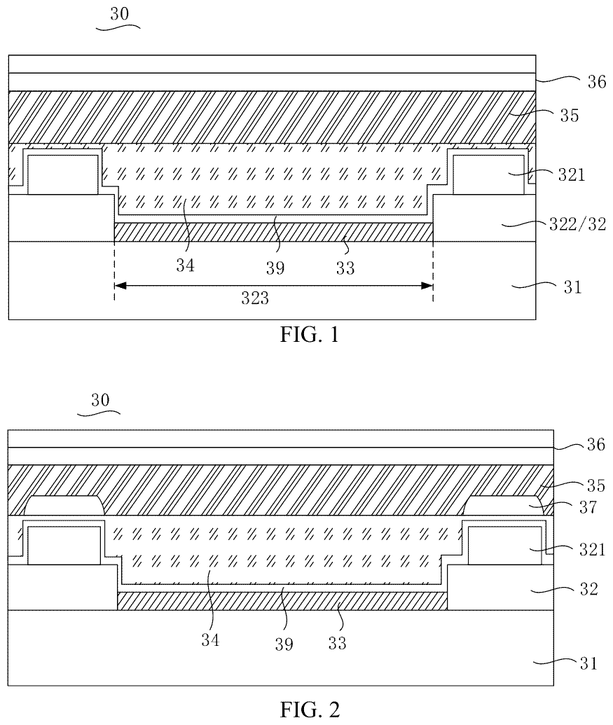

Referring to FIG. 1, as a display panel provided by an embodiment of the present application, the display panel 30 includes a substrate 31, a pixel-defining layer 32, a light-emitting functional layer 33, a first micro-prism structure layer 34, a second micro-prism structure layer 35, and an inorganic encapsulation layer 36. The pixel-defining layer 32 is disposed on the substrate 31, the pixel-defining layer 32 is divided into a plurality of partitions 322, wherein interiors of the plurality of partitions 322 are hollowed out internally to form a plurality of pixel regions 323. The light-emitting functional layer 33 is disposed in the plurality of pixel regions 323. The first micro-prism structure layer 34 is disposed on the light-emitting functional layer 33. The second micro-prism structure layer 35 is disposed on the first micro-prism structure layer 34. The inorganic encapsulation layer 36 is disposed on the second micro-prism structure layer 35. Both the first micro-prism structure layer 34 and the second micro-prism structure layer 35 are organic encapsulation structures, and a refractive index of the second micro-prism structure layer 35 is greater than that of the first micro-prism structure layer 34.

The pixel-defining layer 32 (PDL) is configured to define and limit the shape and size of pixels, ensuring that each pixel is able to work correctly. Specifically, the pixel-defining layer 32 may achieve precise alignment and positioning of pixels, ensure isolation between pixels, prevent crosstalk, and reduce color mixing between adjacent pixels. The pixel-defining layer 32 is mainly fabricated by performing photolithography on photosensitive polyimide (PSPI) material before Active-Matrix Organic Light Emitting Diode (AMOLED) evaporation. The display panel includes a plurality of support structures 321, and the plurality of support structures 321 are located on the pixel-defining layer 32.

The light-emitting functional layer 33 specifically includes an anode, a hole-injection layer (HIL), a hole-transport layer (HTL), a light-emitting auxiliary layer (RGB Prime), an organic light-emitting layer (EML), a hole-blocking layer (HBL), an electron-transport layer (ETL), an electron-injection layer (EIL), and a cathode. The function of the organic light-emitting layer is to convert electrons into light sources, and other organic structures help electrons and holes flow smoothly.

The inorganic encapsulation layer 36 may be a single-layer structure, or a film stack structure with two or more layers. When the inorganic encapsulation layer 36 adopts a two-layer stacked structure, it may be formed by stacking an inorganic insulating layer and an organic insulating layer, that is, the inorganic encapsulation layer 36 is formed by stacking an inorganic insulation structure and an organic insulation structure. Of course, the display panel 30 further includes other structures such as a thin-film transistor and an insulating layer 39, which are not elaborated here.

In the embodiment of the present application, by adding the first micro-prism structure layer 34 and the second micro-prism structure layer 35 on the light-emitting functional layer 33, and with the refractive index value of the second micro-prism structure layer 35 being greater than that of the first micro-prism structure layer 34, the light emitted from the light-emitting functional layer 33 converges towards the middle area of the display panel 30 after passing through the first micro-prism structure layer 34 and the second micro-prism structure layer 35, achieving the effect of increasing the front-side light-emitting brightness of the display panel 30. In this way, under the condition of guaranteeing the front-side light-emitting brightness of the display panel 30, it is possible to avoid increasing the light-emitting brightness of the light-emitting functional layer 33, so as to reduce the power consumption of the product, thereby improving the market competitiveness of the product. Moreover, the first micro-prism structure layer 34 and the second micro-prism structure layer 35 themselves are the encapsulation structures of the display panel 30. No additional film stack structure is incorporated according to the embodiment of the present application, thereby leading to no increase in thickness of the display panel 30.

In the embodiment of the present application, the design of replacing the flat layer with the first micro-prism structure layer 34 eliminates the relatively thick flat-layer structure, which is beneficial to reducing the overall thickness of the display panel 30. Moreover, the prism structure in the embodiment of this application exhibits a better light-concentrating effect since both the first micro-prism structure layer 34 and the second micro-prism structure layer 35 may deflect light at the same time, and the deflection of light rays by the second micro-prism structure layer 35 closer to the light-emitting surface makes the light more concentrated.

Specifically, a range of the refractive index of the first micro-prism structure layer 34 is 1.4 to 1.6, which may meet the refractive-index requirements of low-refractive materials in the micro-prism structure, while a range of the refractive index of the second micro-prism structure layer 35 is 1.7 to 2.0. Through testing, the inventors found that the light emitted from the light-emitting functional layer 33 may be more concentrated towards the pixel region 323, greatly reducing the light directed towards the region of the pixel-defining layer 32, thus achieving the purpose of further improving the light-concentrating effect after adopting the above-mentioned design.

Furthermore, referring to FIG. 2, the display panel 30 includes a plurality of condensing lenses 37. The plurality of condensing lenses 37 are disposed on the plurality of partitions 322 in one-to-one correspondence which formed by the pixel-defining layer 32, and the plurality of condensing lenses 37 are located between the first micro-prism structure layer 34 and the second micro-prism structure layer 35.

In the embodiment of the present application, by further adding the plurality of condensing lenses 37, the plurality of condensing lenses 37 converges the light entering the area of the pixel-defining layer 32 to the pixel region 323, further achieving the purpose of leading to an increase in the brightness of the pixel region.

The plurality of partitions 322 are all square annular structures surrounding the corresponding plurality of pixel regions 323. The plurality of condensing lenses 37 are located on one sidewall of the corresponding plurality of partitions 322, totally reflecting the light on one side of the pixel. Or, the plurality of condensing lenses 37 are located on two opposing sidewalls of the corresponding plurality of partitions 322, such as on the left-and-right sides or the up-and-down sides of the plurality of partitions 322, totally reflecting the light on two sides of the pixel. Or, the plurality of condensing lenses 37 are located on three or four sidewalls of the corresponding plurality of partitions 322. Specifically, the plurality of condensing lenses 37 are located on four opposing sidewalls of the corresponding plurality of partitions 322, which totally reflect the light in more regions and further lead to an increase in the light quantity in the pixel region 323.

Optionally, orthographic projections of the plurality of condensing lenses 37 on the substrate cover orthographic projections of the plurality of partitions 322 on the substrate 31. Through this design, the plurality of condensing lenses 37 are able to receive more light and converge more light to the pixel region. Even, orthographic projections of the plurality of condensing lenses 37 on the substrate 31 partially overlap with an orthographic projection of the light-emitting functional layer 33 on the substrate 31 to totally reflect more light.

In the embodiment of the present application, the first micro-prism structure layer 34 is fabricated after completing the design of the pixel-defining layer 32, the light-emitting functional layer 33, and the insulating layer 39 above them, which to ensure the leveling of the device film-layer structure. The condensing lens 37 may be fabricated on the first micro-prism structure layer 34 by photolithography after the first micro-prism structure layer 34 is leveled and solidified. Then, the second micro-prism structure layer 35 is fabricated to complete the fabrication of all micro-prism structures, realizing the overall functionalization of the first micro-prism structure layer 34, the condensing lens 37, and the second micro-prism structure layer 35. The inorganic encapsulation layer 36 is fabricated after completing the fabrication of the above-mentioned film layers, and finally, the protective film-layer process is completed conventionally.

A height of the first micro-prism structure layer 34 is at least greater than that of each of the plurality of support structures 321 in the pixel-defining layer 32, and it is necessary to ensure the leveling of the film-layer structure.

The manufacturing process of the plurality of condensing lenses 37 is as follows: deposit a film layer on the first micro-prism structure layer 34, and then perform a patterning treatment on the film layer. That is, appropriately expand the opening on the basis of the opening of the pixel-defining layer 32. Generally, a range of the expansion is about 1 to 3μm. Specifically, it is able to be 2 μm, to obtain the plurality of condensing lenses 37. A range of the refractive index of each of the plurality of condensing lenses 37 is 1.4 to 1.6, meeting the refractive-index requirements of low-refractive materials in the micro-prism structure. A low-refractive pattern structure may be obtained by the above design of the first micro-prism structure layer 34 and the condensing lens 37.

During the formation of the second micro-prism structure layer 35, a high-refractive and high-transparent material may be directly formed into a film by a photolithography process to complete the fabrication of the second micro-prism structure layer 35. Specifically, high-refractive particles (such as ZrO₂, etc.) may be mixed when depositing a low-refractive material to achieve high refraction while ensuring that the transmittance does not change significantly. Of course, a high-refractive-index material may be directly deposited to form the second micro-prism structure layer 35.

The embodiment of the present application mainly focuses on the large-thickness light-emitting layer, adjusting its structure so that an additional light-regulating function is added in addition to the packaging and light-emitting functions. Under normal circumstances, the second micro-prism structure layer 35 is formed into a film by printing, and its general thickness is about 30 μm. If the photolithography method is used, the thickness of the second micro-prism structure layer 35 may be reduced to about 5 μm. If the micro-prism functionalization of the light-emitting layer is achieved by the photolithography method, that is, through the combined design of the first micro-prism structure layer 34, the plurality of condensing lenses 37, and the second micro-prism structure layer 35, the overall thickness may be reduced by about 5 μm, and the thickness reduction is quite significant.

In the embodiment of the present application, a thickness of the second micro-prism structure layer 35 is less than that of the first micro-prism structure layer 34. Firstly, the first micro-prism structure layer 34 needs to be higher than the top of the pixel-defining layer 32. This is not only to finely adjust the light emitted from the light-emitting functional layer 33 but to make the top flat. Therefore, the first micro-prism structure layer 34 has certain thickness requirements. Secondly, to avoid a large distance between the pixel-defining layer 32 and the top of the first micro-prism structure layer 34, which may cause part of the light to irradiate the bottom of the plurality of condensing lenses 37 and be reflected onto the pixel-defining layer 32, resulting in light loss. Thirdly, the thickness of the second micro-prism structure layer 35 is greater than that of the plurality of condensing lenses 37. The combination of the second micro-prism structure layer 35 and the plurality of condensing lenses 37 may make more light reach the pixel region. Therefore, the second micro-prism structure layer 35 does not need to be set with a large thickness to meet the light-concentrating requirements and lead to an increase in the front-side light-emitting brightness of the display panel 30.

It should be noted that since neither the first micro-prism structure layer 34 nor the second micro-prism structure layer 35 is a film layer with a uniform thickness, the thickness mentioned here refers to the maximum thickness of the first micro-prism structure layer 34 and the maximum thickness of the second micro-prism structure layer 35.

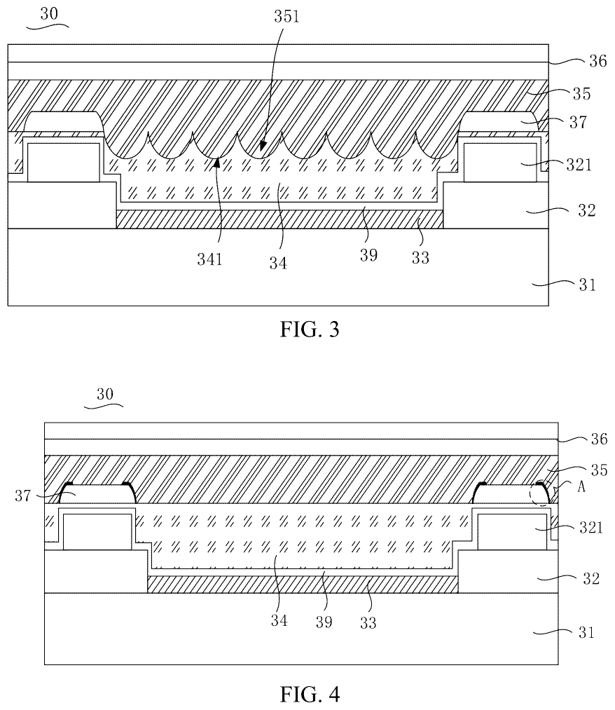

In one or more embodiments, referring to FIG. 3, a side of the first micro-prism structure layer 34 facing the second micro-prism structure layer 35 is provided with a plurality of grooves 341, and a side of the second micro-prism structure layer 35 facing the first micro-prism structure layer 34 is provided with a plurality of protrusions 351. A material of the plurality of protrusions 351 is identical to that of the second micro-prism structure layer 35, that is, the plurality of protrusions 351 are part of the first micro-prism structure layer 34. The plurality of protrusions 351 are abutted against the plurality of grooves 341 in one-to-one correspondence, and the contact surface between the first micro-prism structure layer 34 and the second micro-prism structure layer 35 is uneven.

In the embodiment of the present application, through the improvement of the contact surface between the first micro-prism structure layer 34 and the second micro-prism structure layer 35, after the light emitted from the light-emitting functional layer 33 exits from the uneven surface of the first micro-prism structure layer 34, the light has more deflection directions in terms of angles. At this time, after the plurality of light rays in different directions enter through the uneven surface of the second micro-prism structure layer 35, the plurality of light rays will be more evenly mixed and emitted outwards, avoiding the deflection of the light rays refracted by the first micro-prism structure layer 34 and the second micro-prism structure layer 35 towards the region where the pixel-defining layer 32 is located, and at the same time making the light quantity more uniform everywhere. Moreover, the design of the plurality of condensing lenses 37 is also incorporated into the embodiments of this application. The light rays deflected to the area where the pixel-defining layer 32 is located are converged to the pixel region through the plurality of condensing lenses 37. Thus, under the condition of ensuring the uniformity of the light quantity in the pixel region, the brightness of the pixel region is further increased.

Moreover, in the embodiment of the present application, the first micro-prism structure layer 34 and the second micro-prism structure layer 35 are directly attached without a gap, avoiding the consumption of light quantity between the first micro-prism structure layer 34 and the second micro-prism structure layer 35 or the generation of reverse light deflection.

Further, a cross-section of each of the plurality of grooves 341 is arc-shaped in a thickness direction of the display panel 30, a cross-section of each of the plurality of protrusions 351 is arc-shaped in the thickness direction of the display panel 30. The plurality of grooves 341 and the plurality of protrusions 351 are seamlessly attached. Specifically, the cross-section of the plurality of grooves 341 and the cross-section of the plurality of protrusions 351 are both circular-arc-shaped. Through this setting, the plurality of grooves 341 in the first micro-prism structure layer 34 acts as a concave mirror, dispersing the light emitted from the light-emitting functional layer 33. While the plurality of protrusions 351 in the second micro-prism structure layer 35 acts as a convex mirror, and the second micro-prism structure layer 35 focuses the incident light towards the pixel region, making the brightness of the pixel region higher.

It should be noted that in the embodiment of the present application, since the height of the first micro-prism structure layer 34 is relatively small and close to the height of the pixel-defining layer 32, it is not suitable to set the groove 341 in the region of the pixel-defining layer 32 for the first micro-prism structure layer 34. In the solution with the plurality of condensing lenses 37, the first micro-prism structure layer 34 is not in direct contact with the second micro-prism structure layer 35 in the region of the pixel-defining layer 32 either. Therefore, the plurality of grooves 341 and the plurality of protrusions 351 are only set directly above the light-emitting functional layer 33, that is, the plurality of grooves 341 and the plurality of protrusions 351 are only set in the pixel region, and the plurality of grooves 341 and the plurality of protrusions 351 are only converge the light towards the pixel region rather than converging the light towards the region where the pixel-defining layer 32 is located, thus ensuring the light-emitting brightness of the pixel region.

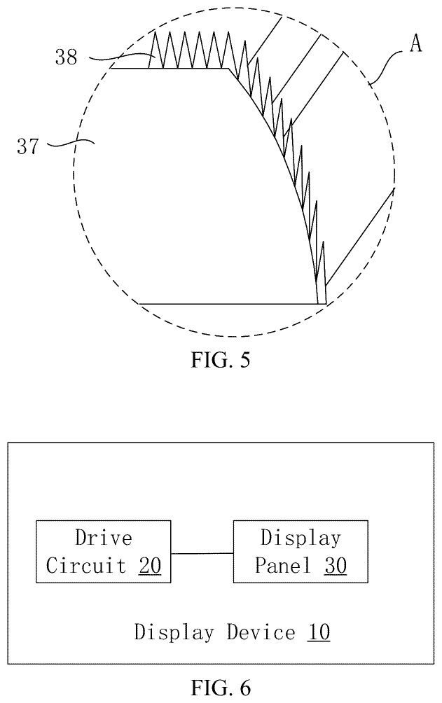

In one or more embodiments, referring to FIG. 4 and FIG. 5, the display panel 30 includes a plurality of micro-triangular prisms 38. The plurality of micro-triangular prisms 38 are disposed on surfaces of the plurality of condensing lenses 37, and all apex angles of the plurality of micro-triangular prisms 38 vertically face toward the inorganic encapsulation layer 36.

In the embodiment of the present application, by adding a plurality of micro-triangular prisms 38 on surfaces of the plurality of condensing lenses 37, for the light incident on the plurality of condensing lenses 37 from different angles, the angles of the light are adjusted by the plurality of micro-triangular prisms 38, further ensuring that the light incident on the plurality of condensing lenses 37 have more opportunities to achieve total reflection, realizing total reflection of light at more angles, and thus improving the light-emitting brightness.

The plurality of micro-triangular prisms 38 are at least disposed on both sides of each of the plurality of condensing lenses 37. As one embodiment, the plurality of micro-triangular prisms 38 are only disposed on both sides of each of the plurality of condensing lenses 37, forming an array of micro-triangular prisms 38 with a height gradient on both sides of the plurality of condensing lenses 37. As another embodiment, the plurality of micro-triangular prisms 38 are simultaneously disposed on both sides of the plurality of condensing lenses 37 and on the side of the plurality of condensing lenses 37 facing the second micro-prism structure layer 35, that is, the plurality of micro-triangular prisms 38 are distributed in an array along the edge of the condensing lens 37. No matter which implementation is adopted, more light may achieve total reflection.

Specifically, on both sides of the plurality of condensing lenses 37, along the direction from the substrate 31 towards the inorganic encapsulation layer 36, the heights of the plurality of micro-triangular prisms 38 gradually increase. By setting in this way, even if the light at some angles passes through the first micro-triangular prism 38 (the micro-triangular prism 38 with a relatively low height) and is not able to undergo total reflection due to insufficient angles, but it may finally meet the total-reflection condition after being modulated by other micro-triangular prisms 38 with different heights subsequently.

Referring to FIG. 6, the embodiment of the present application provides a display device. The display device 10 includes a drive circuit 20 and the display panel 30 as described above. The drive circuit 20 drives the display panel 30. The display device 10 may guarantee display brightness, reducing product power consumption and improving market competitiveness.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a pixel-defining layer, disposed on the substrate, divided into a plurality of partitions, wherein interiors of the plurality of partitions are hollowed out internally to form a plurality of pixel regions;
a light-emitting functional layer, disposed in the plurality of pixel regions;
a first micro-prism structure layer, disposed on the light-emitting functional layer;
a second micro-prism structure layer, disposed on the first micro-prism structure layer; and
an inorganic encapsulation layer, disposed on the second micro-prism structure layer,
wherein both the first micro-prism structure layer and the second micro-prism structure layer are organic encapsulation structures, and a refractive index of the second micro-prism structure layer is greater than that of the first micro-prism structure layer.

2. The display panel according to claim 1, wherein a range of the refractive index of the first micro-prism structure layer is 1.4 to 1.6, and a range of the refractive index of the second micro-prism structure layer is 1.7 to 2.0.

3. The display panel according to claim 1, wherein a side of the first micro-prism structure layer facing the second micro-prism structure layer is provided with a plurality of grooves, a side of the second micro-prism structure layer facing the first micro-prism structure layer is provided with a plurality of protrusions;
a material of the plurality of protrusions is identical to that of the second micro-prism structure layer, and the plurality of protrusions are abutted against the plurality of grooves in one-to-one correspondence.

4. The display panel according to claim 3, wherein a cross-section of each of the plurality of grooves is arc-shaped in a thickness direction of the display panel, a cross-section of each of the plurality of protrusions is arc-shaped in the thickness direction of the display panel, and the plurality of protrusions are abutted against the plurality of grooves in one-to-one correspondence.

5. The display panel according to claim 1, wherein the inorganic encapsulation layer is formed by stacking inorganic insulation structure and organic insulation structure.

6. The display panel according to claim 1, wherein the display panel comprises a plurality of support structures, the plurality of support structures are located on the pixel-defining layer, and a height of the first micro-prism structure layer is greater than that of each of the plurality of support structures.

7. The display panel according to claim 1, wherein the display panel comprises a plurality of condensing lenses, the plurality of condensing lenses are disposed on the plurality of partitions in one-to-one correspondence, the plurality of condensing lenses are located between the first micro-prism structure layer and the second micro-prism structure layer.

8. The display panel according to claim 7, wherein orthographic projections of the plurality of condensing lenses on the substrate cover orthographic projections of the plurality of partitions on the substrate.

9. The display panel according to claim 7, wherein the display panel comprises a plurality of micro-triangular prisms, the plurality of micro-triangular prisms are disposed on surfaces of the plurality of condensing lenses, and all apex angles of the plurality of micro-triangular prisms vertically face toward the inorganic encapsulation layer.

10. The display panel according to claim 9, wherein the plurality of micro-triangular prisms are at least disposed on both sides of each of the plurality of condensing lenses.

11. The display panel according to claim 10, wherein elevations of the plurality of micro-triangular prisms gradually increase on both sides of the plurality of condensing lenses and along a direction from the substrate towards the inorganic encapsulation layer.

12. The display panel according to claim 7, wherein the plurality of partitions are all square annular structures surrounding the corresponding plurality of pixel regions, and the plurality of condensing lenses are located on one sidewall of the corresponding plurality of partitions.

13. The display panel according to claim 7, wherein the plurality of partitions are all square annular structures surrounding the corresponding plurality of pixel regions, and the plurality of condensing lenses are located on two opposing sidewalls of the corresponding plurality of partitions.

14. The display panel according to claim 7, wherein the plurality of partitions are all square-shaped ring structures, each partition surrounds the corresponding pixel region, and the plurality of condensing lenses are located on the four side walls of the plurality of corresponding partitions.

15. The display panel according to claim 7, wherein orthographic projections of the plurality of condensing lenses on the substrate partially overlaps with an orthographic projection of the light-emitting functional layer on the substrate.

16. The display panel according to claim 7, wherein a range of the refractive index of each of the plurality of condensing lenses is 1.4 to 1.6.

17. The display panel according to claim 7, wherein a thickness of the second micro-prism structure layer is less than that of the first micro-prism structure layer.

18. A display panel, comprising:
a substrate;
a pixel-defining layer, disposed on the substrate, divided into a plurality of partitions, wherein interiors of the plurality of partitions are hollowed out internally to form a plurality of pixel regions;
a light-emitting functional layer, disposed in the plurality of pixel regions;
a first micro-prism structure layer, disposed on the light-emitting functional layer;
a second micro-prism structure layer, disposed on the first micro-prism structure layer, a thickness of the second micro-prism structure layer is less than that of the first micro-prism structure layer;
an inorganic encapsulation layer, disposed on the second micro-prism structure layer; and
a plurality of condensing lenses, disposed on the plurality of partitions in one-to-one correspondence, the plurality of condensing lenses are located between the first micro-prism structure layer and the second micro-prism structure layer, and orthographic projections of the plurality of condensing lenses on the substrate cover orthographic projections of the plurality of partitions on the substrate;
wherein both the first micro-prism structure layer and the second micro-prism structure layer are organic encapsulation structures, and a refractive index of the second micro-prism structure layer is greater than that of the first micro-prism structure layer.

19. A display device, comprising a drive circuit and a display panel, the drive circuit drives the display panel, the display panel comprises:
a substrate;
a pixel-defining layer, disposed on the substrate, divided into a plurality of partitions, wherein interiors of the plurality of partitions are hollowed out internally to form a plurality of pixel regions;
a light-emitting functional layer, disposed in the plurality of pixel regions;
a first micro-prism structure layer, disposed on the light-emitting functional layer;
a second micro-prism structure layer, disposed on the first micro-prism structure layer; and
an inorganic encapsulation layer, disposed on the second micro-prism structure layer;
wherein both the first micro-prism structure layer and the second micro-prism structure layer are organic encapsulation structures, and a refractive index of the second micro-prism structure layer is greater than that of the first micro-prism structure layer.
